(19) United States
(12) Patent Application Publication
(10) Pub. No.: US 2014/0154479 A1
(43) Pub. Date: Jun. 5, 2014

(54) RESIN COMPOSITION FOR PRINTED CIRCUIT BOARD, INSULATING FILM, PREPREG AND PRINTED CIRCUIT BOARD

(71) Applicant: SAMSUNG ELECTRO-MECHANICS CO., LTD., Suwon (KR)

(72) Inventors: Geum Hee Yun, Suwon (KR); Jin Ho Hong, Suwon (KR); Sa Yong Lee, Suwon (KR); Jin Young Kim, Suwon (KR); Keun Yong Lee, Suwon (KR)

(73) Assignee: SAMSUNG ELECTRO-MECHANICS CO., LTD., Suwon (KR)

(21) Appl. No.: 13/845,032

(22) Filed: Mar. 17, 2013

(30) Foreign Application Priority Data
Nov. 30, 2012 (KR) 10-2012-0138214

(51) Int. Cl. H05K 1/03; H01B 3/40

(52) U.S. Cl. CPC H05K 1/0373; H01B 3/40
USPC 428/195.1; 523/456; 523/435

(57) ABSTRACT

Disclosed herein is a resin composition for a printed circuit board, including: a liquid crystalline oligomer; an epoxy resin; and an inorganic filler which is a reaction product of silica, silane having a vinyl group and an alkoxy group, and vinyl or hydroxyl terminated silicone oil. The resin composition has a low thermal expansion coefficient, excellent heat resistance and a high glass transition temperature.

### CROSS REFERENCE TO RELATED APPLICATION

This application claims the benefit of Korean Patent Application No. 10-2012-0138214, filed Nov. 30, 2012, entitled “Resin composition for printed circuit board, insulating film, prepreg and printed circuit board”, which is hereby incorporated by reference in its entirety into this application.

### BACKGROUND OF THE INVENTION

1. Technical Field

The present invention relates to a resin composition for a printed circuit board, an insulating film, a prepreg and a printed circuit board.

2. Description of the Related Art

According to the advancement of electronic appliances having complicated functions, printed circuit boards are becoming lighter, thinner and smaller day by day. In order to satisfy such requirements, the wiring of a printed circuit board is becoming more complicated, highly-densified and highly-functionalized. Further, in printed circuit boards, buildup layers are laminated, and thus wiring is required to be fine and highly-dense. As such, in printed circuit boards, electrical, thermal and mechanical properties are increasingly important factors.

Consequently, a prepreg and a copper clad laminate (CCL) used in a printed circuit board must be made thinner while maintaining the electrical, thermal and mechanical properties of conventional printed circuit boards.

However, as printed circuit boards become lighter, thinner and smaller, there occurs a problem of printed circuit boards being warped. That is, as a printed circuit board becomes thin, its strength become low, so it can be warped when it is mounted with components at high temperature, thereby causing defects. Therefore, in order to minimize the warpage of a printed circuit board occurring when a reflow process is performed during a chip (component) mounting process, characteristics of low thermal expansion coefficient (CTE), high glass temperature (Tg) and high modulus are very important. For this purpose, the thermal expansion characteristics and heat resistance of a thermosetting polymer resin act as important factors, and are closely influenced by the structure of the thermosetting polymer resin and the network between the chains of the thermosetting polymer resin.

Meanwhile, in the case of a conventional prepreg or a conventional copper clad laminate, an insulating material is prepared by charging a resin layer, such as an epoxy resin layer, a polyimide resin layer, an aromatic polyester resin layer or the like, with a ceramic filler, such as silica, alumina or the like, but the insulation property thereof is not sufficient. Further, in the case of a conventional prepreg or a conventional copper clad laminate, it is difficult to reduce the warpage of a printed circuit board. For example, Patent Document 1 discloses an epoxy resin composition including a liquid crystalline oligomer. However, this epoxy resin composition is problematic in that the network between an inorganic filler and a polymer resin cannot be sufficiently formed, so its thermal expansion coefficient cannot be sufficiently decreased to such as degree that it can be suitably used for a printed circuit board, and its glass transition temperature cannot be increased.

Patent Document 1: Korean Unexamined Patent Application Publication No. 10-2011-0108198

### SUMMARY OF THE INVENTION

In order to improve the thermal and mechanical properties of an insulation material of a printed circuit board, the present inventors have developed an inorganic filler, which can be chemically bonded with a liquid crystalline oligomer (LCO) or a soluble liquid crystalline thermosetting oligomer (LCTO) and an epoxy resin, and which can be chemically bonded with a glass fiber used as a reinforcing agent of a prepreg. The present invention was completed based on this inorganic filler.

Accordingly, the present invention intends to provide a resin composition for a printed circuit board, which has high heat resistance and mechanical strength, and which has excellent warpage characteristics and chemical resistance necessary for realizing process stability while having a low dielectric constant and low hygrosopicity.

Further, the present invention intends to provide an insulating film having a low thermal expansion coefficient and a high glass transition temperature which is fabricated using the resin composition.

Further, the present invention intends to provide a prepreg having a low thermal expansion coefficient and a high glass transition temperature which is impregnated with the resin composition.

Further, the present invention intends to provide a printed circuit board including the insulating film or the prepreg.

In order to accomplish the above objects, a first aspect of the present invention provides a resin composition for a printed circuit board, including: a liquid crystalline oligomer; an epoxy resin; and an inorganic filler which is a reaction product of silica, silane having a vinyl group and an alkoxy group, and vinyl or hydroxyl terminated silicone oil.

In the resin composition, the liquid crystalline oligomer is represented by Formula 1, 2, 3 or 4 below:

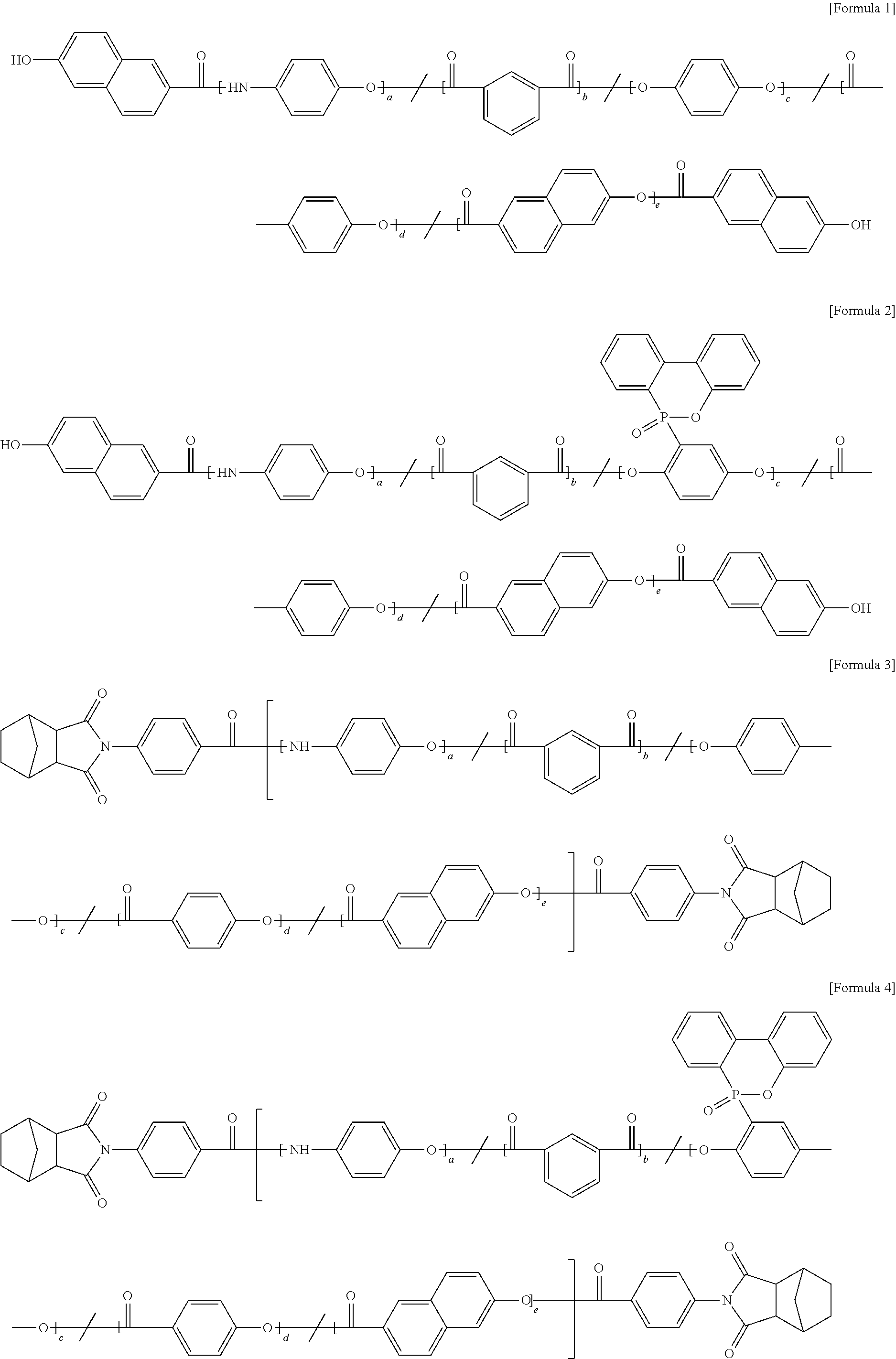

wherein a is an integer of 13˜26, b is an integer of 13˜26, c is an integer of 9˜21, d is an integer of 10˜30, and e is an integer of 10˜30.

In the resin composition, the epoxy resin is represented by Formula 5 or 6 below:

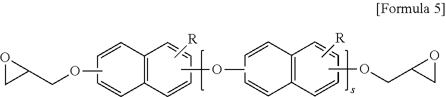

wherein R is an alkyl group of 1˜20 carbon atoms, and n is an integer of 0˜20,

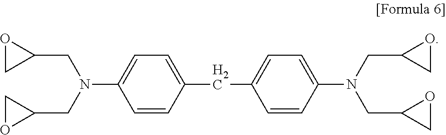 [SMILES: c1cc(N(CC2CO2)CC2CO2)ccc1Cc1ccc(N(CC2CO2)CC2CO2)cc1]

In the resin composition, the resin composition may include 0.5 to 50 wt % of the liquid crystalline oligomer, 5 to 50 wt % of the epoxy resin, and 40 to 80 wt % of the inorganic filler.

In the resin composition, the liquid crystalline oligomer may have a number average molecular weight of 2500 to 6500.

In the resin composition, the epoxy resin may be at least one selected from the group consisting of a naphthalene-based epoxy resin, a bisphenol A epoxy resin, a phenol novolac epoxy resin, a cresol novolac epoxy resin, a rubber-modified epoxy resin, and a phosphorus-based epoxy resin.

In the resin composition, the inorganic filler may be a reaction product of 100 parts by weight of silica, 0.1 to 20 parts by weight of silane having a vinyl group and an alkoxy group, and 0.1 to 20 parts by weight of vinyl or hydroxyl terminated silicone oil.

In the resin composition, the silane having a vinyl group and an alkoxy group may be vinyl tetraethyl silane.

In the resin composition, the vinyl or hydroxyl terminated silicone oil may be hydroxy terminated silicone oil, vinyl terminated-vinyl penetrated silicone oil or a mixture thereof.

The resin composition may further include at least one selected from the group consisting of an amide-based curing agent, a polyamine-based curing agent, an acid anhydride curing agent, a phenol novolac curing agent, a polymercaptan curing agent, a tertiary amine curing agent, and an imidazole curing agent.

The resin composition may further include at least one selected from the group consisting of a metal-based curing accelerator, an imidazole-based curing accelerator, and an amine-based curing accelerator.

The resin composition may further include at least one thermoplastic resin selected from the group consisting of a phenoxy resin, a polyimide resin, a polyamide-imide (PAI) resin, a polyether-imide (PEI) resin, a polysulfone (PS) resin, a polyether sulfone (PES) resin, a polyphenylene ether (PPE) resin, a polycarbonate (PC) resin, a polyether ether ketone (PEEK) resin, and a polyester resin.

A second aspect of the present invention provides an insulating film formed of the resin composition.

A third aspect of the present invention provides a prepreg formed by impregnating a substrate with the resin composition.

A fourth aspect of the present invention provides a printed circuit board comprising the insulation film.

A fifth aspect of the present invention provides a printed circuit board comprising the prepreg.

### BRIEF DESCRIPTION OF THE DRAWINGS

The above and other objects, features and advantages of the present invention will be more clearly understood from the following detailed description taken in conjunction with the accompanying drawing, in which:

FIG. 1 is a sectional view showing a general printed circuit board to which a resin composition of the present invention can be applied.

[Reference Numerals]

| | |
|---|---|
| 100: printed circuit board | 110: insulator |

| | |
|---|---|
| 120: electronic component | 130: buildup layer |
| 131: insulating layer | 132: circuit layer |

| | |
|---|---|
| 140: capacitor | 150: resistor |

160: solder resist
170: external connection means
180: pad

### DESCRIPTION OF THE PREFERRED EMBODIMENTS

Prior to the detailed description of the present invention, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

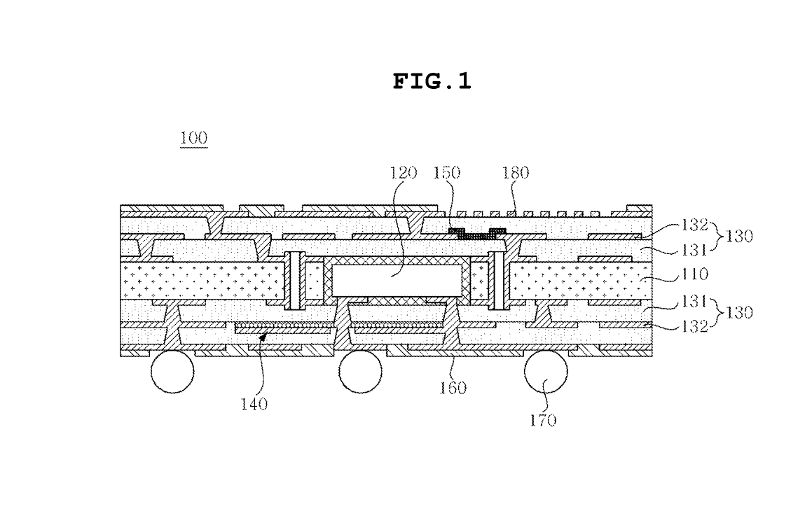

FIG. 1 is a sectional view showing a general printed circuit board to which a resin composition of the present invention can be applied. Referring to FIG. 1, a printed circuit board 100 may be a board embedded with an electronic component. Specifically, the printed circuit board 100 may includes an insulator or prepreg 100 having a cavity, an electronic component 120 disposed in the cavity, and a build-up layer 130 including the electronic component. The build-up layer 130 may include an insulating layer 131 disposed on at least one of the upper and lower sides of the insulator or prepreg 110 and a circuit layer 132 disposed on the insulating layer 131 to provide an interlayer connection.

Here, the electronic component 120 may be an active device such as a semiconductor device or the like. Further, the printed circuit board 100 may be provided therein with only one electronic component 120 or may further be provided therein with at least one electronic component such as a capacitor 140 or a resistor 150, and the number and kind of electronic components are not limited. Here, the insulator or prepreg 110 and the insulating layer 131 serve to provide an insulation property between circuit layers or between electronic components, and serve as structural materials for maintaining the strength of a package.

In this case, when the density of wiring of the printed circuit board 100 increases, the insulator or prepreg 110 and the insulating layer 131 need low dielectric characteristics in order to reduce the noise between circuit layers and decrease the parasitic capacitance thereof, and need low dielectric loss characteristics in order to increase insulation characteristics.

As such, at least one of the insulator or prepreg 110 and the insulating layer 131 must have a low thermal expansion coefficient, high heat resistance and high mechanical strength, and must have excellent warpage characteristics and chemical resistance necessary for realizing process stability while having a low dielectric constant and low hygrosopicity.

In the present invention, in order to improve the strength of the insulator or prepreg 110 by lowering the thermal expansion coefficient thereof and increasing the glass transition temperature thereof, the insulator or prepreg 110 may be formed of a resin composition including: a liquid crystalline oligomer; an epoxy resin; and an inorganic filler which is a reaction product of silica, silane having a vinyl group and an alkoxy group, and vinyl or hydroxyl terminated silicone oil.

Liquid Crystalline Oligomer

A liquid crystalline oligomer, preferably, a liquid crystalline oligomer represented by Formulae 1 to 4 below includes an ester group for improving dielectric tangent and dielectric constant and a naphthalene group for improving crystallinity at both ends of a main chain thereof, and may include a phosphorous component for imparting flame retardancy as represented by Formula 2 or 4. In detail, the liquid crystalline oligomer includes a hydroxy group or a nadimide group at the end thereof, and thus can conduct a thermocuring reaction with an epoxy resin.

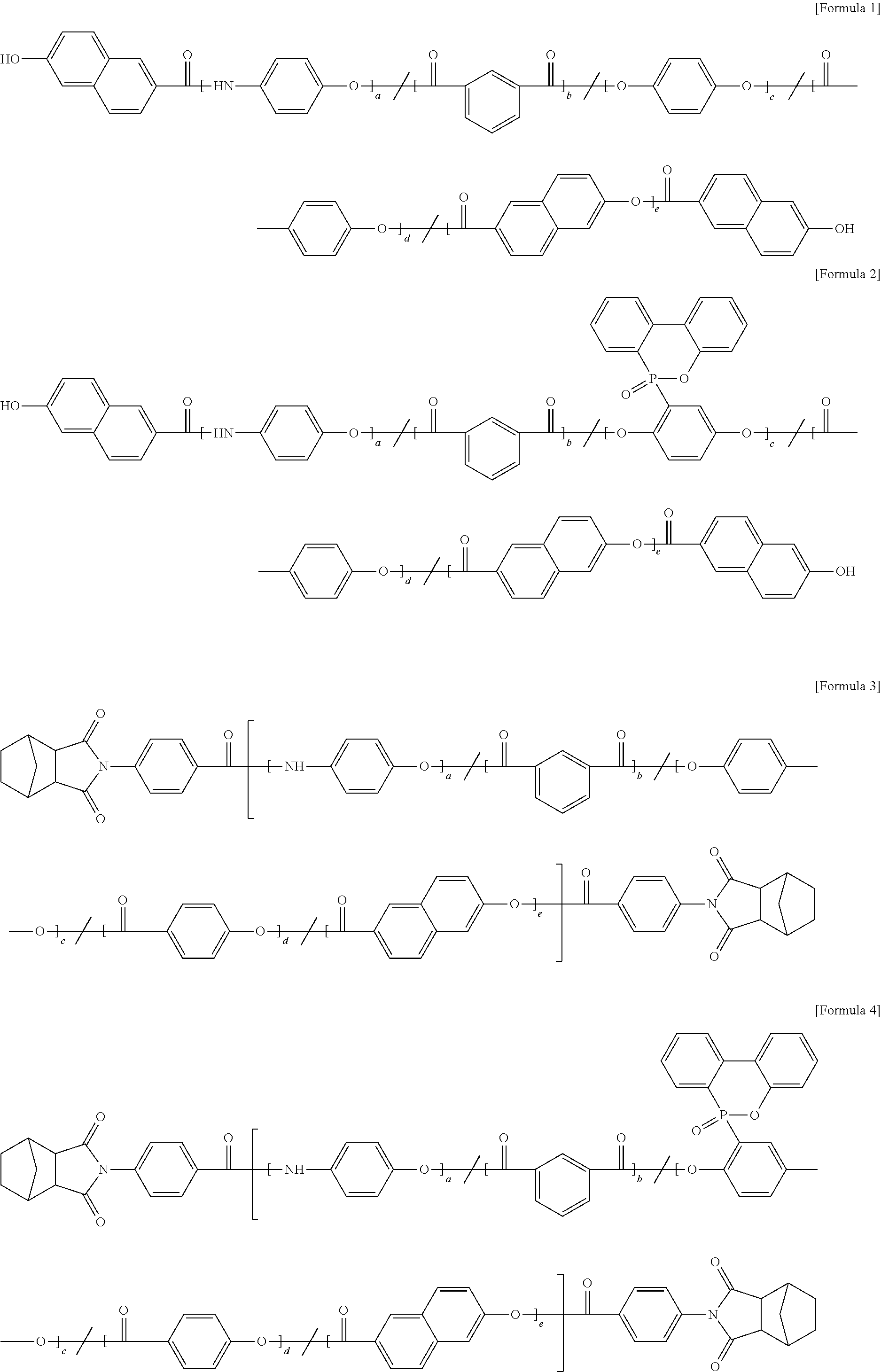

In the above Formulae 1 to 4, a is an integer of 13˜26, b is an integer of 13˜26, c is an integer of 9˜21, d is an integer of 10˜30, and e is an integer of 10˜30.

The liquid crystalline oligomer may have a number average molecular weight of 2500 to 6500 g/mol, preferably 3,000 to 6,000 g/mol, and more preferably 4,500 to 5,500 g/mol. When the number average molecular weight of the liquid crystalline oligomer is less than 2,500 g/mol, there is a problem of mechanical properties becoming weak, and when the number average molecular weight thereof is more than 6,500 g/mol, there is a problem of solubility becoming low.

The amount of the liquid crystalline oligomer used may be 0.5 to 50 wt %, and preferably 15 to 40 wt %. When the amount thereof is less than 0.5 wt %, there is a problem of a thermal expansion coefficient decreasing and a glass transition temperature being slightly improved, and when the amount thereof is more than 50 wt %, there is problem of mechanical properties deteriorating.

Epoxy Resin

The resin composition according to the present invention includes an epoxy resin in order to increase the treatability of the resin composition to an adhesive film. The epoxy resin is not particularly limited, but may be an epoxy resin including one or more epoxy groups in a molecule thereof, preferably two or more epoxy groups in a molecule thereof, and preferably four or more epoxy groups in a molecule thereof.

The epoxy resin used in the present invention may be an epoxy resin including a naphthalene group as represented by Formula 5 below, and, preferably, may be an epoxy resin including an aromatic amine as represented by Formula 6 below.

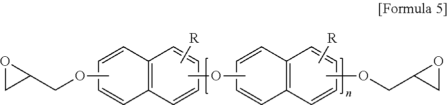

In the above Formula 5, R is an alkyl group of 1˜20 carbon atoms, and n is an integer of 0˜20.

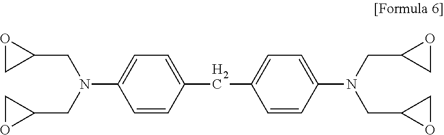 [SMILES: c1cc(N(CC2CO2)CC2CO2)ccc1Cc1ccc(N(CC2CO2)CC2CO2)cc1]

However, the epoxy resin used in the present invention is not limited to the epoxy resin represented by Formula 5 or 6. Examples of the epoxy resin may include a bisphenol A epoxy resin, a bisphenol F epoxy resin, a bisphenol S epoxy resin, a phenol novolac epoxy resin, an alkylphenol novolac epoxy resin, a biphenyl epoxy resin, an aralkyl epoxy resin, a dicyclopentadiene epoxy resin, a naphthalene-based epoxy resin, a naphthol epoxy resin, an epoxy resin of a condensate of phenol and aromatic aldehyde having a phenolic hydroxyl group, a biphenylaralkyl epoxy resin, a fluorene epoxy resin, a xanthene epoxy resin, triglycidylisocyanurate, a rubber-modified epoxy resin, and a phosphorus-based epoxy resin. Preferably, examples of the epoxy resin may include a naphthalene-based epoxy resin, a bisphenol A epoxy resin, a phenol novolac epoxy resin, a cresol novolac epoxy resin, a rubber-modified epoxy resin, and a phosphorus-based epoxy resin. These epoxy resins may be used in the form of a mixture.

The amount of the epoxy resin used may be 5 to 50 wt %. When the amount thereof is less than 5 wt %, there is a problem of treatability decreasing, and when the amount thereof is more than 50 wt %, there is problem of the degree of improvement of a dielectric tangent, a dielectric constant and a thermal expansion coefficient decreasing because of the addition amount of other components relatively decreasing.

Inorganic Filler

The resin composition according to the present invention includes an inorganic filler in order to decrease the thermal expansion coefficient of an epoxy resin. The inorganic filler serves to increase the thermal expansion coefficient of an epoxy resin, and the amount of the inorganic filler in the resin composition is varied depending on the use of the resin composition. Preferably, the amount of the inorganic filler in the resin composition may be 40 to 80 wt %. When the amount thereof is less than 40 wt %, there is a problem of a dielectric tangent becoming low and a thermal expansion coefficient becoming high, and when the amount thereof is more than 80 wt %, there is a problem of adhesive strength deteriorating.

Generally, in an insulation resin, in order to improve moisture resistance, an inorganic filler surface-treated with a silane coupling agent, preferably, silica having a diameter of 0.008 to 5 μm may be used. However, in the present invention, a reaction product of silica, silane having a vinyl group and an alkoxy group, and vinyl or hydroxyl terminated silicone oil is used as the inorganic filler.

According to the present invention, an alkoxy group of silane having many hydroxy groups, vinyl groups (coupling agent) and alkoxy groups on the surface of silica, for example, vinyl tetraethyl silane (VTES) represented by Formula 7 below are chemically reacted to be connected with each other. Then, when the vinyl group of the silane is chemically reacted with the vinyl group or hydroxy group of silicone oil, silicone oil, which is an inorganic polymer, is disposed between silica fillers, thus improving the strength of a resin and remarkably increasing curing density. Moreover, the hydroxy group of the silicone oil reacts with an epoxy resin, the vinyl group of the silicon oil and/or the substituent group of a glass fiber to realize ultra-low thermal expansion coefficient characteristics, thereby improving physical and thermal characteristics. That is, an inorganic filler such as silica is connected with an inorganic polymer such as silicone oil, thus enhancing the interaction between the inorganic filler and the silicon oil.

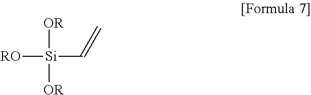

Here, R is a substituent group of 1 to 10 carbon atoms.

Meanwhile, the inorganic filler according to the present invention is obtained by reacting 0.1 to 20 parts by weight of silane having a vinyl group and an alkoxy group and 0.1 to 20 parts by weight of vinyl or hydroxyl terminated silicone oil with 100 parts by weight of silica. In this case, when the amount of the silane is less than 0.1 parts by weight, the addition effect thereof is slight, and when the amount thereof is more than 20 parts by weight, the addition effect of the inorganic filler is reduced because unreacted silane exists. Further, when the amount of the silicon oil is less than 0.1 parts by weight, the addition effect thereof is slight, and when the amount thereof is more than 20 parts by weight, the addition effect of the inorganic filler is reduced because unreacted silicone oil exists.

Examples of the silicon oil may include hydroxyl terminated silicone oil represented by Formula 8 below, vinyl terminated-vinyl penetrated silicone oil represented by Formula 9 below, and a mixture thereof.

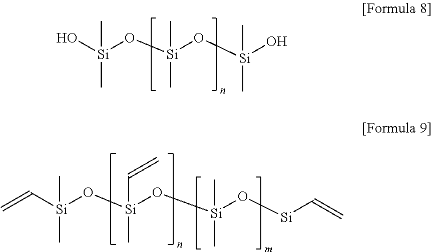

Here, n and m are each an integer of 1 or more.

Moreover, the inorganic filler may be pulverized to a size of several nanometers to several tens of micrometers and then used, or it may be mixed and then used without pulverizing. When the average particle size of the inorganic filler is more than 10 μm, it is difficult to stably form a micropattern at the time of forming a circuit pattern on a conductor layer, and thus it is more preferred that the average particle size of the inorganic filler be 10 μm or less.

Curing Agent

Meanwhile, in the present invention, a curing agent may be selectively used. The curing agent is not particularly limited as long as it can be used to cure an epoxy resin.

Specific examples of suitable curing agents may include: amide-based curing agents such as dicyandiamide and the like; polyamine-based curing agents such as diethylenetriamine, triethylenetetramine, N-aminoethylpiperazine, diaminodiphenylmethane, adipic acid dihydrazide and the like; acid anhydride curing agents such as pyromellitic anhydride, benzophenone tetracarboxylic anhydride, ethyleneglycol bistrimellitic anhydride, glycerol tris-trimellictic anhydride, maleic methylcyclohexene tetracarboxylic anhydride and the like; phenol novolac curing agents; polymercaptan curing agents such as trioxanetrimesitylene mercaptan and the like; tertiary amine curing agents such as benzyldimethylamine, 2,4,6-tris(dimethylamimnomethyl)phenol and the like; and an imidazole curing agent such as 2-ethyl-4-methyl imidazole, 2-methyl imidazole, 1-benzyl-2-methyl imidazole, 2-heptadecyl imidzazole, 2-undecyl imidazole, 2-phenyl-4-methyl-5-hydroxymethyl imidazole, 2-phenyl imidazole, 2-phenyl-4-methyl imidazole, 1-benzyl-2-phenyl imidazole, 1,2-dimethyl imidazole, 1-cyanoethyl-2-phenyl imidazole, 2-phenyl-4,5-dihydroxymethyl imidazole and the like. These curing agents may be used in the form of a mixture. In particular, it is preferred that dicyandiamide be used as the curing agent in terms of physical properties. The curing agent can be used in an amount of 0.1 to 1 parts by weight based on 100 parts by weight of a mixture of the liquid crystalline oligomer and the epoxy resin such that the intrinsic physical properties of the epoxy resin does not deteriorate and curing speed is considered.

Curing Accelerator

The resin composition of the present invention may selectively include a curing accelerator to efficiently cure the resin composition. Examples of the curing accelerator used in the present invention may include a metal-based curing accelerator, an imidazole-based curing accelerator, and an amine-based curing accelerator. These curing accelerators may be used in the form of combinations thereof in an amount commonly-used in the related field.

The metal-based curing accelerator is not particularly limited, but may be an organic metal complex of a metal, such as cobalt, copper, zinc, iron, nickel, manganese, tin or the like, or an organic metal salt. Specific examples of the organic metal complex may include: organic cobalt complexes such as cobalt (II) acetylacetonate, cobalt (III) acetylacetonate and the like; organic copper complexes such as copper (II) acetylacetonate and the like; organic zinc complexes such as zinc (II) acetylacetonate and the like; organic iron complexes such as iron (III) acetylacetonate and the like; organic nickel complexes such as nickel (II) acetylacetonate and the like; and organic manganese complexes such as manganese (II) acetylacetonate and the like. Specific examples of the organic metal salt may include zinc octylate, tin octylate, zinc naphthenate, cobalt naphthenate, tin stearate, zinc stearate and the like. In terms of curability and solvent solubility, cobalt (II) acetylacetonate, cobalt (III) acetylacetonate, zinc (II) acetylacetonate, zinc naphthenate or iron (III) acetylacetonate may be preferably used as the metal-based curing accelerator. More preferably, cobalt (II) acetylacetonate or zinc naphthenate may be used as the metal-based curing accelerator. These metal-based curing accelerators may be used in the form of a combination thereof.

Examples of the imidazole-based curing accelerator may include, but are not limited to, imidazole compounds, such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidzolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adducts, 2-phenylimidazole isocyanuric acid adducts, 2-phenyl-4,5-dihydroxymethylimidazole, 2-phenyl-4-methyl-5-hydroxymethylimidazole, 2,3-dihydroxy-1H-pyroro[1,2-a]benzimidazole, 1-dodecyl-2-methyl-3-benzylimidazolium chloride, 2-methylimidazoline, 2-phenylimidazoline; and adducts of the imizazole compounds and epoxy resins. These imidazolel-based curing accelerators may be used in the form of a combination thereof.

Examples of the amine-based curing accelerator may include, but are not limited to, amine compounds such as trialkylamines (triethylamine, tributylamine, etc.), 4-dimethylaminopyridine, benzyldimethylamine, 2,4,6-tris(dimethylaminomethyl)phenol, and 1,8-diazabicyclo(5,4,0)-undecene (hereinafter, referred to as “DBU”). These amine-based curing accelerators may be used in the form of a combination thereof.

Thermoplastic Resin

The resin composition of the present invention may selectively include a thermoplastic resin in order to improve the film properties of the resin composition or the mechanical properties of a cured product. Examples of the thermoplastic resin may include a phenoxy resin, a polyimide resin, a polyamide-imide (PAI) resin, a polyether-imide (PEI) resin, a polysulfone (PS) resin, a polyether sulfone (PES) resin, a polyphenylene ether (PPE) resin, a polycarbonate (PC) resin, a polyether ether ketone (PEEK) resin, and a polyester resin. These thermoplastic resins may be used independently or in a combination thereof. The thermoplastic resin may have a weight average molecular weight of 5,000 to 200,000. When the weight average molecular weight thereof is less than 5,000, there is a problem in that the effect of improving film forming properties or mechanical strength is not sufficiently exhibited, and when the weight average molecular weight is more than 200,000, there are problems in that the compatibility of the thermoplastic resin with the liquid crystalline oligomer and the epoxy resin is not sufficient, the unevenness of the surface of a cured product increases, and it is difficult to form high-density micropatterns.

The weight average molecular weight of the thermoplastic resin was measured at a column temperature of 40° C. using a measuring meter (LC-9A/RID-6A, manufactured by Shimadzu Seisakusho Corporation), a column (Shodex K-800P/K-804L/K-804L, manufactured by Showa Denko Corporation) and a moving bed (chloroform (CHCl₃)), and was calculated using a standard polystyrene calibration curve.

When the thermoplastic resin is mixed with the resin composition of the present invention, the amount of the thermoplastic resin in the resin composition is not particularly limited, but may be 0.1 to 10 wt %, preferably, 1 to 5 wt % based on 100 wt % of the nonvolatile content of the resin composition. When the amount of the thermoplastic resin is less than 0.1 wt %, there is a problem in that the effect of improving film forming properties or mechanical strength is not exhibited, and when the weight average molecular weight is more than 10 wt %, there are problems in that the melting viscosity of the resin composition increases and the surface roughness of an insulating layer after a wet process increases.

The resin composition of the present invention is mixed in the presence of an organic solvent. Considering the solubility and mixability of the resin and other additives used in the present invention, examples of the organic solvent may include, but are not limited to, 2-methoxy ethanol, acetone, methyl ethyl ketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethylformamide, and dimethylacetamide.

The viscosity of the resin composition according to the present invention may be 700 to 1500 cps. In this case, the resin composition is suitable for forming an insulating film, and maintains appropriate adhesiveness at room temperature. The viscosity of the resin composition can be adjusted by changing the content of a solvent. The amount of non-volatile components in the resin composition excluding a solvent may be 30 to 70 wt %. When the viscosity of the resin composition deviates from the range, it is difficult to form an insulating film, or it is difficult to form the insulating film into a member even though the insulating film is formed.

Further, the peel strength of the insulating film formed of the resin composition to copper foil having a thickness of 12 μm may be 1.0 kN/m or more. The insulating film formed of the resin composition of the present invention may have a thermal expansion coefficient (CTE) of 15 ppm/° C. or less, preferably, 10 ppm/° C. or less, and may have a glass transition temperature (Tg) of 220 to 300° C., preferably, 250 to 270° C.

Besides, if necessary, the resin composition of the present invention may further include a commonly-known leveling agent and/or flame retardant.

The resin composition of the present invention can be formed into a semisolid dry film by a general method commonly known in the related field. For example, the resin composition is formed into a film using a roll coater, a curtain coater or the like, and then the film is dried to form a semisolid dry film. This semisolid dry film is used as an insulating layer (insulating film) or a prepreg by applying it onto a substrate at the time of manufacturing a multi-layered printed circuit board using a build-up method. Such an insulation film or prepreg may have a low thermal expansion coefficient (CTE) of 50 ppm/° C. or less.

As described above, the resin composition of the present invention is impregnated into a substrate such as a glass fiber or the like, and is then cured to prepare a prepreg, and then the prepreg is laminated with copper foil to obtain a copper clad laminate (CCL). Further, the insulating film formed of the resin composition of the present invention is laminated on a copper clad laminate (CCL), which is used as an inner layer at the time of manufacturing a multi-layered printed circuit board, to manufacturing a multi-layered printed circuit board. For example, the insulating film formed of the resin composition is laminated on a patterned inner layer, cured at a temperature of 80 to 110° C. for 20 to 30 minutes, desmeared, and then formed with a circuit layer by electroplating, thereby manufacturing a multi-layered printed circuit board.

Hereinafter, the present invention will be described in more detail with reference to the following Examples and Comparative Examples. However, the scope of the present invention is not limited thereto.

### Preparation Example 1

### Preparation of Liquid Crystalline Oligomer

218.26 g (2.0 mol) of 4-aminophenol, 415.33 g (2.5 mol) of isophthalic acid, 276.24 g (2.0 mol) of 4-hydroxybenzoic acid, 282.27 g (1.5 mol) of 6-hydroxy-2-naphthoic acid, 648.54 g (2.0 mol) of 9,10-dihydro-9-oxa-10-phosphaphenanthrene-10-oxide (DOPO) and 1531.35 g (15.0 mol) of acetic anhydride were put into a 20 L glass reactor. Subsequently, the reactor was sufficiently filled with nitrogen gas, the temperature in the reactor was increased to 230° C. under a nitrogen gas flow, and then reflux was performed for 4 hours while maintaining the temperature in the reactor. Subsequently, 188.18 g (1.0 mol) of 6-hydroxy-2-naphthoic acid was added, and then acetic acid and unreacted acetic anhydride, which are reaction by-products, was removed to prepare a liquid crystalline oligomer having a molecular weight of about 4500 and represented by Formula 2 above.

### Example 1

262.5 g of silica having a size distribution of an average particle size of 0.2 to 1 μm, 2.63 g of a mixture (weight ratio: 1:1) of vinyl terminated-vinyl penetrated silicone oil (manufactured by KCC Corporation in Korea) and hydroxy terminated silicone oil (manufactured by KCC Corporation in Korea) and 5.25 g of vinyl tetraethyl silane (VTES) were added to 102.42 g of N,N′-dimethylacetamide (DMAc) to obtain a slurry. In this case, the slurry was stirred for 2 hours using a homogenizer. Subsequently, 95.17 g of a mixture (weight ratio: 1:1) of a liquid crystalline oligomer and N,N′-dimethylacetamide (DMAc) were added to the stirred slurry, and then 31.72 g of an epoxy resin (Araldite MY-721, manufactured by Huntsmann Corporation), 0.32 g of dicyandiamide as a curing catalyst and 0.13 g of azobisisobutyronitrile (AIBN) were further added to prepare a varnish. In this case, 0.2 g of nitric acid was used as a catalyst. The solid content of the varnish was 70 wt %. Subsequently, this varnish was applied to the shiny surface of copper foil to a thickness of 100 μm by a doctor blade method to form a film. Subsequently, the film was dried at room temperature for 2 hours, dried in a vacuum oven at 80° C. for 1 hour and then dried at 110° C. for 1 hour to be semicured (B-stage). Then, the semicured film was completely cured at vacuum pressure. In this case, the maximum temperature was 230° C., and the maximum pressure was 2 MPa.

### Example 2

### Preparation of Prepreg

A glass fiber (2116, manufactured by Nittobo Corporation) was uniformly impregnated with the varnish prepared in Example 1. The glass fiber impregnated with the varnish passed through a heating zone at 200° C. to be semicured, thus obtaining a prepreg. In this case, the amount of a polymer in the prepreg was 54 wt %.

### Comparative Example 1

50 g of a liquid crystalline oligomer was added to N,N′-dimethylacetamide (DMAc) to prepare a liquid crystalline oligomer solution. 107.09 g of a silica filler slurry (NV 78.13%) was stirred for about 30 minutes. 33.3 g of an epoxy resin (Araldite MY-721, manufactured by Huntsmann Corporation), 0.33 g of dicyandiamide as a curing catalyst were added to the crystalline oligomer solution and the silica filler slurry, and then stirred for 2 hours to prepare a varnish. Subsequently, this varnish was applied to the shiny surface of copper foil to a thickness of 100 μm by a doctor blade method to form a film. Subsequently, the film was dried at room temperature for 2 hours, dried in a vacuum oven at 80° C. for 1 hour and then dried at 110° C. for 1 hour to be semicured (B-stage). Then, the semicured film was completely cured at vacuum pressure. In this case, the maximum temperature was 230° C., and the maximum pressure was 2 MPa.

### Comparative Example 2

A glass fiber (2116, manufactured by Nittobo Corporation) was uniformly impregnated with the varnish prepared in Comparative Example 1. The glass fiber impregnated with the varnish passed through a heating zone at 200° C. to be semicured, thus obtaining a prepreg. In this case, the amount of a polymer in the prepreg was 54 wt %.

Measurement of Thermal Characteristics

The thermal expansion coefficient (CTE) of each of the insulation film and prepreg samples prepared in Examples 1 and 2 and Comparative Examples 1 and 2 were measured using a thermomechanical analyzer (TMA), and the glass transition temperature (Tg) thereof was measured using a differential scanning calorimetry (DSC) after increasing the temperature of a thermomechanical analyzer (TMA 2940, manufactured by TA Instruments Corporation) to 270° C. (first cycle) and 300° C. (second cycle) at a heating rate of 10° C./min under a nitrogen atmosphere. The results thereof are given in Tables 1 and 2 below.

Measurement of Elastic Modulus and Viscosity

The Young's modulus (GPa) of each of the insulation film and prepreg samples of Example 1 and Comparative Example 1 and storage modulus of each of the insulation film and prepreg samples of Example 2 and Comparative Example 2 were measured as the elastic moduli, and the viscosity of each of the insulation film and prepreg samples of Example 1 and Comparative Example 1 was measured using a Brookfield viscometer. The results thereof are given in Tables 1 and 2 below.

TABLE 1

| | Thermal | Glass | | |
|---|---|---|---|---|
| | expansion | transition | Young's | |
| | coefficient | temperature | modulus | Viscosity |
| | (ppm/° C.) | (° C.) | (GPa) | (Cp) |
| Ex. 1 | 13.8 | 220 | 12.3 | 467 |
| Comp. Ex. 1 | 19.4 | 200 | 10.8 | 650 |

TABLE 2

| Class. | | Ex. 2 | Comp. Ex. 2 |
|---|---|---|---|
| Glass transition temperature (° C.) | | 260 | 235 |
| Thermal expansion coefficient (ppm/° C.) | | 4.2 | 6.1 |
| Storage modulus | at 25° C. | 32 | 29 |
| | at 250° C. | 22 | 18 |

From Tables 1 and 2, it can be ascertained that the thermal expansion coefficients (CTEs) of the insulation film and prepreg samples of Examples 1 and 2, in which an inorganic filler obtained by bonding silica particles with each other using vinyl or hydroxyl terminated silicone oil was used, are lower than those of the insulation film and prepreg samples of Comparative Examples 1 and 2, in which only silica was used and that the glass transition temperatures (Tg) of the insulation film and prepreg samples of Examples 1 and 2 are lower than those of the insulation film and prepreg samples of Comparative Examples 1 and 2. Further, it can be ascertained that the Young's modulus (GPa) and storage modulus of the insulation film and prepreg samples of Examples 1 and 2 were improved compared to those of the insulation film and prepreg samples of Comparative Examples 1 and 2.

As described above, the resin composition for a printed circuit board according to the present invention and the insulation film and prepreg formed using the resin composition have excellent heat resistance and mechanical strength, and have excellent warpage characteristics and chemical resistance necessary for realizing process stability while having a low dielectric constant and low hygrosopicity.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A resin composition for a printed circuit board, comprising:
a liquid crystalline oligomer;
an epoxy resin; and
an inorganic filler which is a reaction product of silica, silane having a vinyl group and an alkoxy group, and vinyl or hydroxyl terminated silicone oil.

2. The resin composition of claim 1, wherein the liquid crystalline oligomer is represented by Formula 1, 2, 3 or 4 below: 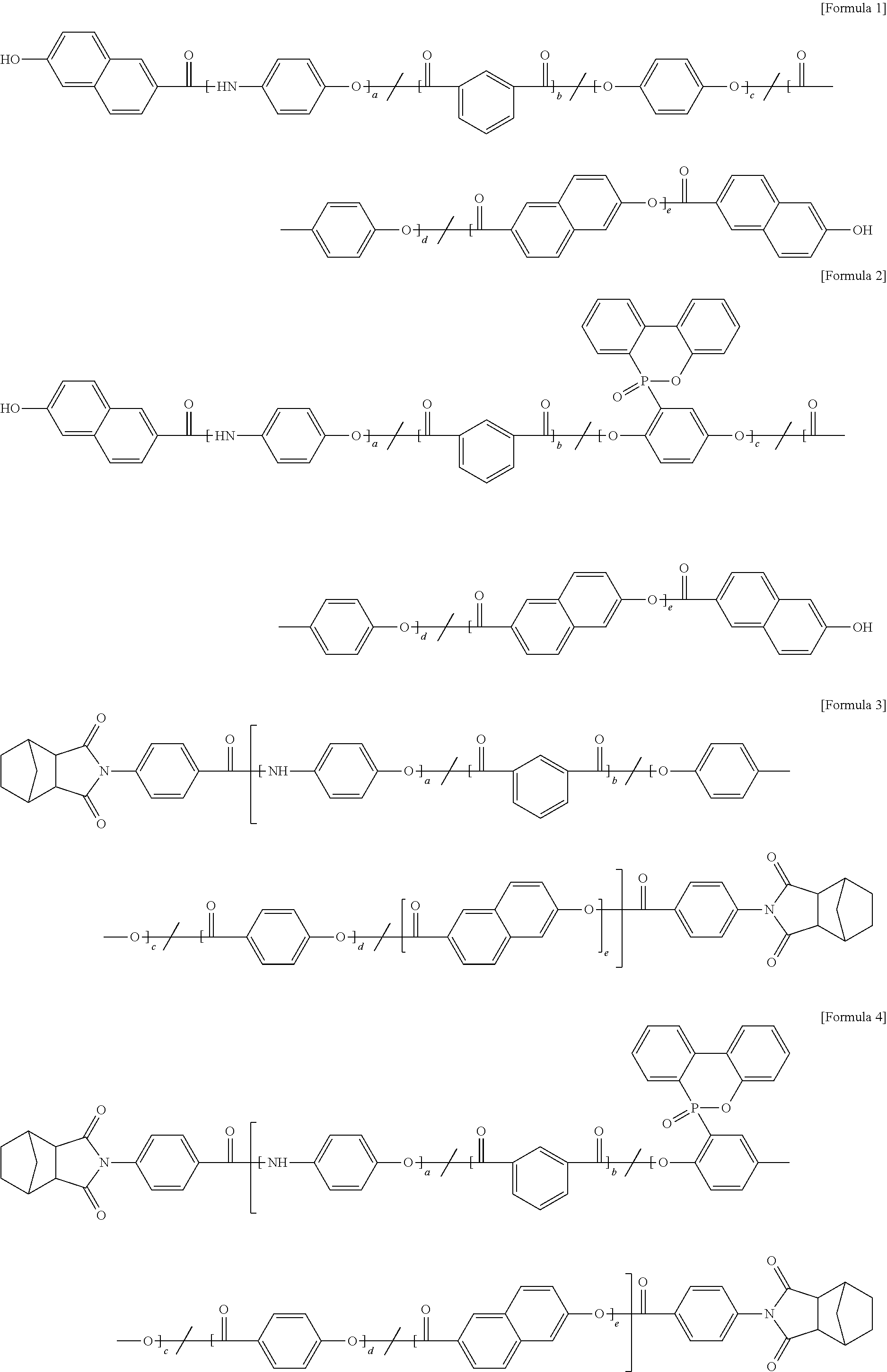
wherein a is an integer of 13˜26, b is an integer of 13˜26, c is an integer of 9˜21, d is an integer of 10˜30, and e is an integer of 10˜30.

3. The resin composition of claim 1, wherein the epoxy resin is represented by Formula 5 or 6 below: 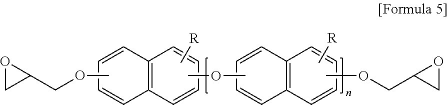
wherein R is an alkyl group of 1˜20 carbon atoms, and n is an integer of 0˜20,

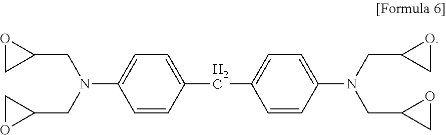 [SMILES: c1cc(N(CC2CO2)CC2CO2)ccc1Cc1ccc(N(CC2CO2)CC2CO2)cc1]

4. The resin composition of claim 1, wherein the resin composition comprises 0.5 to 50 wt % of the liquid crystalline oligomer, 5 to 50 wt % of the epoxy resin, and 40 to 80 wt % of the inorganic filler.

5. The resin composition of claim 1, wherein the liquid crystalline oligomer has a number average molecular weight of 2500 to 6500.

6. The resin composition of claim 1, wherein the epoxy resin is at least one selected from the group consisting of a naphthalene-based epoxy resin, a bisphenol A epoxy resin, a phenol novolac epoxy resin, a cresol novolac epoxy resin, a rubber-modified epoxy resin, and a phosphorus-based epoxy resin.

7. The resin composition of claim 1, wherein the inorganic filler is a reaction product of 100 parts by weight of silica, 0.1 to 20 parts by weight of silane having a vinyl group and an alkoxy group, and 0.1 to 20 parts by weight of vinyl or hydroxyl terminated silicone oil.

8. The resin composition of claim 1, wherein the silane having a vinyl group and an alkoxy group is vinyl tetraethyl silane.

9. The resin composition of claim 1, wherein the vinyl or hydroxyl terminated silicone oil is hydroxy terminated silicone oil, vinyl terminated-vinyl penetrated silicone oil or a mixture thereof.

10. The resin composition of claim 1, further comprising at least one selected from the group consisting of an amide-based curing agent, a polyamine-based curing agent, an acid anhydride curing agent, a phenol novolac curing agent, a polymercaptan curing agent, a tertiary amine curing agent, and an imidazole curing agent.

11. The resin composition of claim 1, further comprising at least one selected from the group consisting of a metal-based curing accelerator, an imidazole-based curing accelerator, and an amine-based curing accelerator.

12. The resin composition of claim 1, further comprising at least one thermoplastic resin selected from the group consisting of a phenoxy resin, a polyimide resin, a polyamide-imide (PAI) resin, a polyether-imide (PEI) resin, a polysulfone (PS) resin, a polyether sulfone (PES) resin, a polyphenylene ether (PPE) resin, a polycarbonate (PC) resin, a polyether ether ketone (PEEK) resin, and a polyester resin.

13. An insulating film formed of the resin composition of claim 1.

14. A prepreg formed by impregnating a substrate with the resin composition of claim 1.

15. A printed circuit board comprising the insulation film of claim 13.

16. A printed circuit board comprising the prepreg of claim 14.
